(19) United States
(12) Patent Application Publication
(10) Pub. No.: US 2021/0037651 A1
(43) Pub. Date: Feb. 4, 2021

(54) ELECTRIC CIRCUIT DEVICE AND METHOD FOR PRODUCING CIRCUIT BOARD

(71) Applicant: HITACHI AUTOMOTIVE SYSTEMS, LTD., Hitachinaka-shi, Ibaraki (JP)

(72) Inventor: Kiminori MUTO, Hitachinaka-shi, Ibaraki (JP)

(73) Assignee: HITACHI AUTOMOTIVE SYSTEMS, LTD., Hitachinaka-shi, Ibaraki (JP)

(21) Appl. No.: 16/981,751

(22) PCT Filed: Mar. 12, 2019
(86) PCT No.: PCT/JP2019/009849

§ 371 Date: Sep. 17, 2020

(30) Foreign Application Priority Data
Mar. 19, 2018 (JP) 2018-050392

(51) Int. Cl. H05K 1/18; H05K 1/11; H05K 3/28; H05K 3/30

(52) U.S. Cl. CPC H05K 1/181; H05K 1/111; H05K 2201/10015; H05K 3/305; H05K 2201/10621; H05K 3/28

(57) ABSTRACT

A land (22) and a wiring pattern (25a) are formed on a component mounting surface (3A) of a circuit board (3), and the wiring pattern (25a) is covered with a solder resist layer (26). An electrode part (21c) of an aluminum electrolytic capacitor (21) is soldered to the land (22) via a solder (27). An intermediate film (24a) formed of a part of a silk pattern (24) is printed on the solder resist layer (26), and by a thermosetting adhesive (23), the aluminum electrolytic capacitor (21) is bonded to the intermediate bonding film (24a). By the intermediate bonding film (24a), the stress of the adhesive (23) at the time of thermal shrinking is relaxed.

### TECHNICAL FIELD

The present invention relates to an electronic circuit device in which a circuit board is accommodated in a housing and a method for producing the circuit board.

### BACKGROUND TECHNOLOGY

When an electronic component is surface-mounted on a circuit board by a reflow soldering method, in order to suppress the falling-off of the electronic component in a reflow soldering process, the electronic component is usually fixed to the circuit board with an adhesive in advance.

For example, in a patent document 1, when a BGA-type electronic component is reflow-soldered, a part of a package of the electronic component is fixed with an adhesive constituting mainly a thermosetting resin.

However, as mentioned above, if the adhesive is applied to the surface of the circuit board to fix the electronic component, stress is generated to the surface of the circuit board to which the adhesive is bonded due to the shrinking at the time when the adhesive is cured.

For example, in a case where a thin wiring pattern covered with an insulation film (so called solder resist) exists under the application region of the adhesive, force is applied to the wiring pattern along the surface direction of the board due to the shrinking of the adhesive, and the break of the wiring pattern might occur. In addition, if the wiring pattern is formed while avoiding the application region of the adhesive, the area where the wiring of the wiring pattern can be carried out decreases.

### PRIOR ART REFERENCE

### Patent Document

Patent Document 1: Japanese Patent Application Publication 2008-78431

### SUMMARY OF THE INVENTION

An electronic circuit device according to the present invention includes:

a housing; and

a circuit board accommodated in the housing and including an electronic component surface-mounted thereon,

wherein a component mounting surface of the circuit board is provided with an insulation film for covering a wiring pattern and a land exposed from the insulation film,

wherein the electronic component includes an electrode part connected to the land by soldering and a non-electrode part fixed to the insulation film via an adhesive element, and

wherein, in the surface of the circuit board, an intermediate bonding film is provided at a part to which the adhesive element is disposed so as to be superposed on the insulation film, and the intermediate bonding film is interposed between the adhesive element and the insulation film.

According to such a configuration, since the intermediate bonding film is interposed between the adhesive element and the insulation film, stress applied to the insulation film due to the shrinking of the adhesive element becomes weak.

In addition, a method for producing a circuit board according to the present invention includes:

forming a wiring pattern and a land to each of a first surface and a second surface of the circuit board, and applying an insulation film so as to cover the wiring pattern;

forming an intermediate bonding film to a part corresponding to a mounting position of a first electronic component in the first surface, so as to be superposed on the insulation film;

soldering an electrode part of the first electronic component to the land by a reflow soldering method after the first electronic component is bonded and fixed on the intermediate bonding film via an adhesive element, in a posture in which the first surface faces upward; and

soldering an electrode part of a second electronic component to the land in the second surface by a reflow soldering method, in a posture in which the second surface faces upward.

In this producing method, although the first electronic component is fixed via the adhesive element to suppress the falling-off of the first electronic component at the time of the reflow soldering of the second electronic component, as mentioned above, since the intermediate bonding film is interposed between the adhesive element and the insulation film, stress applied to the circuit board due to the shrinking of the adhesive element becomes weak.

According to the preset invention, since the intermediate bonding film is interposed between the adhesive element for fixing the electronic component and the insulation film, stress applied to the insulation film due to the shrinking of the adhesive element becomes weak. Therefore, for example, even in a case where the adhesive element is provided so as to be superposed on the wiring pattern, the possibility of the break of the wiring pattern becomes small.

### BRIEF DESCRIPTION OF THE DRAWINGS

FIG. 1 is a perspective exploded view of an electronic circuit device according to the present invention.

FIG. 2 is a perspective view showing a mounting state of an aluminum electrolytic capacitor in a circuit board.

FIG. 3 is a flowchart showing a producing process of the circuit board.

FIG. 4 is a plane view showing an A-surface of the circuit board in a stage in which a silk pattern is formed by printing.

FIG. 5 is a plane view showing a B-surface of the circuit board in a stage in which a silk pattern is formed by printing.

FIG. 6 is an explanatory view of a process showing a mounting process of the aluminum electrolytic capacitor.

FIG. 7 is an explanatory view schematically showing a cross section of a main part of the circuit board mounted with the aluminum electrolytic capacitor.

### MODE FOR IMPLEMENTING THE INVENTION

In the following, one embodiment of the present invention will be explained in detail based on the drawings.

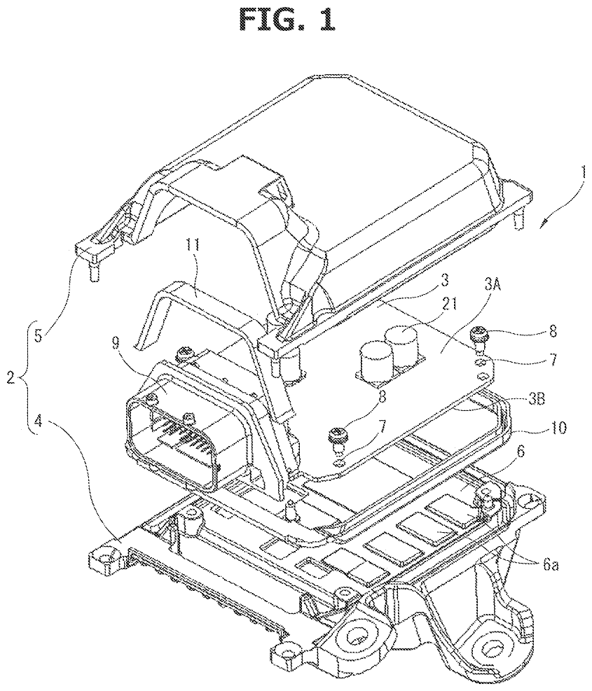

FIG. 1 is a perspective exploded view of an electronic circuit device 1 that is one embodiment of the present invention. The electronic circuit device 1 is one mounted on an appropriate position of a vehicle, as, for example, a controller of an automatic transmission for a vehicle, and is provided with a housing 2 and a circuit board 3 accommodated inside the housing 2. The housing 2 is composed of a metal body 4 including a heat sink portion 6a formed by making a bottom wall 6 thick partially at a plurality of positions on the upper surface of the bottom wall 6 having a rectangular shape, and of a relatively thin metal cover 5 having a swollen shape so as to cover the upper surface of the bottom wall 6. The circuit board 3 having a rectangular shape is provided with, at the periphery thereof, a plurality of mounting holes 7, and is fixed to the body 4 with screws 8 which pass through the respective mounting holes 7. A connector 9 made of synthetic resin which is used for connecting a power supply line and a signal line together is attached to one end portion of the circuit board 3. The space between the body 4 and the cover 5 is sealed by a gasket 10 formed in a continuous frame shape and a gasket 11 for the connector which has a U-shape. The connector gasket 11 is interposed between the connector 9 and the cover 5.

The circuit board 3 is a double-side board or a multilayer board made of a metal base material or a resin base material, such as a glass epoxy resin, and includes, as component mounting surfaces, a first surface 3A (hereinafter is referred to as an A-surface) facing the cover 5 side and a second surface 3B (hereinafter is referred to as a B-surface) facing the body 4 side, and electronic components are surface-mounted on each of the surfaces. Specifically, a plurality of relatively large (in other words, the height from the mounting surface is high) electronic components, such as an aluminum electrolytic capacitor 21, are mounted on the A-surface 3A, and relatively small (in other words, the height from the mounting surface is low) electronic components, such as a CPU and an IC chip, are mounted on the B-surface 3B. In accordance with the difference in the height of the electronic components, the middle part of the cover 5 is swollen upward so as to ensure a sufficient space between the A-surface 3A and the cover 5, such that the electronic components, such as the aluminum electrolytic capacitor 21, do not interfere with the cover 5. In contrast, the B-surface 3B is located close to the bottom wall 6 of the body 4 with a relatively small space, so as to be in a state in which the top surface of a package for an electronic component having a large heating amount, such as a CPU, comes in contact with the surface of the heat sink portion 6a via a heat transfer sheet or a heat transfer grease.

Solder resist as an insulation film is applied to the entire surface of each of the A-surface 3A and the B-surface 3B of the circuit board 3, except through holes and lands to which the soldering of the electronic components is carried out. That is, although lands and wiring patterns are formed on the surface of the base material constituting the circuit board 3 by, for example, etching of a metal foil layer (for example, copper foil), the wiring patterns are covered with a solder resist layer, and the lands are exposed from the solder resist layer.

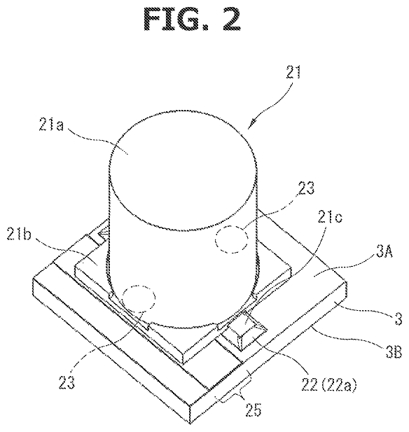

FIG. 2 shows a cylindrical aluminum electrolytic capacitor 21 as an example of a large electronic component mounted on the A-surface 3A. The aluminum electrolytic capacitor 21 is attached in an upright state in which the central axis of a cylindrical part 21a is orthogonal to the surface of the circuit board 3, and is provided with a rectangular seat part 21b at the one end of the cylindrical part 21a. Electrode parts 21c protrude outside from the respective middle parts of two sides of the seat part 21b which face each other. The electrode parts 21c are soldered to respective lands 22 disposed on the A-surface 3A of the circuit board 3. By the soldering carried out to the two parts, the electrode parts 21c are electrically connected to the lands 22, and, simultaneously, the aluminum electrolytic capacitor 21 is fixed to the circuit board 3. Moreover, since the aluminum electrolytic capacitor 21 is a large electronic component, to ensure the attachment to the circuit board 3, the seat part 21b is bonded to the circuit board 3 with adhesive elements, such as adhesives 23 having thermosetting property. Specifically, in two positions along the direction orthogonal to the arrangement direction of a pair of the soldered portions (that is, the electrode parts 21c), the adhesives 23 are arranged so as to have substantially circular shapes, and by the adhesives 23 disposed to the respective two positions, the back surface of the seat part 21b is adhesively fixed to the surface of the circuit board 3. Since solder resist as an insulation film is applied to the entire surface of the circuit board 3, except the lands 22 to be soldered, the aluminum electrolytic capacitor 21 is bonded onto a solder resist layer via the adhesives 23.

Here, intermediate bonding films (not shown in FIG. 2) are locally provided on the solder resist layer at the respective parts where the adhesives 23 are arranged in the A-surface 3A of the circuit board 3. Therefore, actually, the intermediate bonding films are interposed between the adhesives 23 and the solder resist layer.

In addition, there is a case where the part where the adhesive 23 is arranged overlaps with a wiring pattern in the A-surface 3A of the circuit board 3. In an example of FIG. 2, a plurality of thin wiring patterns are formed in the belt-like range shown by a reference number “25” for explanation, and the adhesive 23 is applied so as to be superposed on the wiring patterns covered with the solder resist layer via the inter mediate bonding film.

In an example, the intermediate bonding film is made from a coating film formed, by printing, on the solder resist layer. More specifically, it is made from a part of a silk pattern including characters and numerals displayed on the solder resist layer as an insulation film.

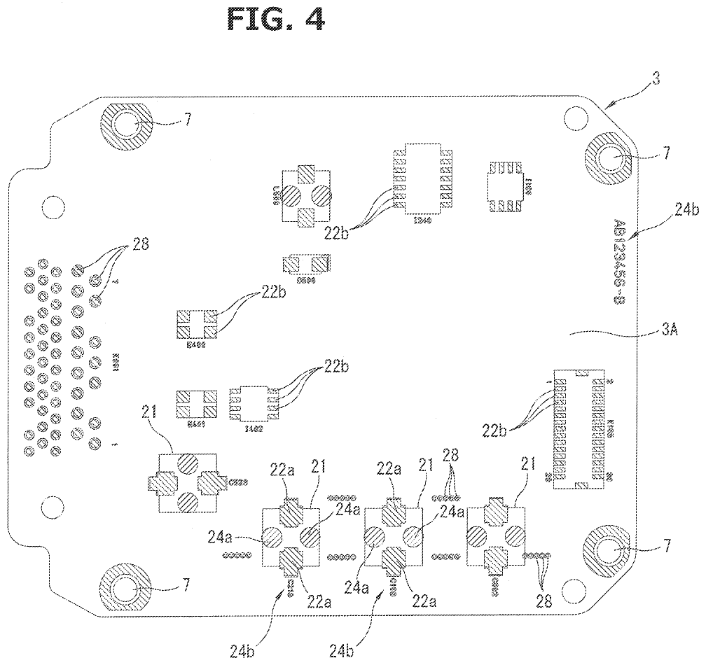

FIG. 4 shows a configuration of the A-surface 3A of the circuit board 3 before electronic components, such as the aluminum electrolytic capacitor 21, are mounted. In addition, to facilitate understanding, the outer shapes of the electronic components, such as the aluminum electrolytic capacitor 21, to be mounted are shown by a solid line. As shown in FIG. 4, the lands 22 to which the electrode parts (for example, the electrode parts 21c) of the electronic components, such as the aluminum electrolytic capacitor 21, are soldered are formed on the surface which becomes the component mounting surface of the circuit board 3. Here, in FIG. 4, in particular, a reference number “22a” is applied to lands 22 corresponding to electrode parts 21c of each aluminum electrolytic capacitor 21, and a reference number “22b” is applied to a land 22 corresponding to an electrode part corresponding to another electronic component. These lands 22 are appropriately connected by a plurality of wiring patterns formed of metal foil layers with the lands 22. Then, a solder resist layer is provided to the entire surface of the A-surface 3A except the lands 22, and the wiring patterns are covered with this solder resist layer. The circuit board 3 is further provided with a plurality of through holes 28 penetrating the circuit board 3, and, similar to the lands 22, the metal foil layer part around each of the through holes 28 is also not covered with the solder resist layer so as to be exposed. In FIG. 4, the metal foil layers of the lands 22 and the like which are exposed from the solder resist layer is shown by hatching.

The solder resist layer is formed by developing type solder resist formed in such a manner that ultraviolet rays are irradiated through a mask after resist ink is sprayed, and then carrying out developing processing so as to form a solder resist layer at a required position.

As a silk pattern 24, characters and numerals showing product numbers (for example, “AB123456-B” in FIG. 4), characters and numerals showing the reference numbers of components to be mounted (for example, “C218” in FIG. 4), a bar code (not shown in the drawings) and the like are formed, by printing, on the surface of the cured solder resist layer. Then, the intermediate bonding film for the adhesive 23 mentioned above is formed by printing as a part of the silk pattern 24. In FIG. 4, reference number “24a” is applied to a part of the silk pattern 24 which becomes the intermediate bonding film for the adhesive 23, and reference number “24b” is applied to characters of other general silk pattern 24. In other words, the silk pattern 24b of characters and numbers and the intermediate bonding film 24a are simultaneously formed by printing with the same ink material.

As mentioned above, a pair of intermediate bonding films 24a provided so as to correspond to the region of each aluminum electrolytic capacitor 21 is provided along the direction orthogonal to the direction in which a pair of lands 22 (22a) is arranged corresponding to a pair of electrode parts 21c. Adhesives 23 are each supplied in a dot shape by a dispenser in a component mounting process and are each expanded in a circular shape at the time of bonding, and each intermediate bonding film 24a is formed in a circular shape. In particular, each of the intermediate bonding films 24a is formed in a larger range than the final forming range of each of the adhesives 23, such that the adhesives 23 each expanded in a circular shape at the time of bonding do not project from the respective intermediate bonding films 24. In FIG. 4, the silk patterns 24a and 24b are shown by hatching having lines whose inclination direction is different from that of the metal foil layer of each of the lands 22 and the like.

In addition, in an example of the drawing, in the A-surface 3A, although the adhesives 23 are not used to electronic components other than the aluminum electrolytic capacitors 21 and the intermediate bonding films 24a are therefore not formed, adhesives 23 and the corresponding intermediate bonding films 24a may be provided when necessary from the viewpoints of holding strength and the like.

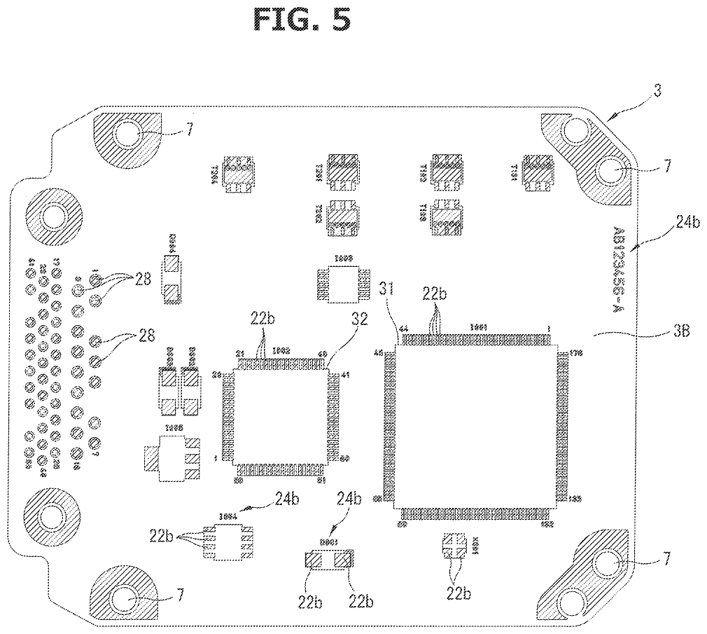

FIG. 5 shows a configuration of the B-surface 3B of the circuit board 3 before electronic components are mounted thereon. In addition, the same as FIG. 4, to facilitate understanding, the outer shapes of electronic components to be mounted are each shown by a solid line, and, for example, a CPU 31 and an IC chip 32 for driver are mounted on the B-surface 3B. Also in this B-surface 3B, a plurality of lands 22b and wiring patterns (not shown) are formed by etching of a metal foil layer, and, on this metal foil layer, a solder resist layer as an insulation film is formed to the entire surface of the B-surface 3B except surrounding parts of the lands 22b and through holes 28.

In addition, similar to the A-surface 3A, characters and numerals showing product numbers and component reference numbers are shown on the solder resist layer. However, the adhesives 23 are not used to low-height electronic components in the B-surface 3B, and the intermediate bonding films 24a corresponding to the adhesives 23 are therefore not equipped.

The mounding of the electronic components in the A-surface 3A and the mounting of the electronic components in the B-surface 3B are each carried out by a reflow soldering method. That is, the soldering is carried out by, after solder material as solder paste is disposed on the lands 22 (22a, 22b) of the A-surface 3A and the B-surface 3B, which become component mounting surfaces, in advance, mounting (temporarily placing) electronic components, and melting the solder material by heating in a reflow furnace. This reflow soldering, namely, the mounting of the electronic components is carried out in the order of the A-surface 3A and the B-surface 3B.

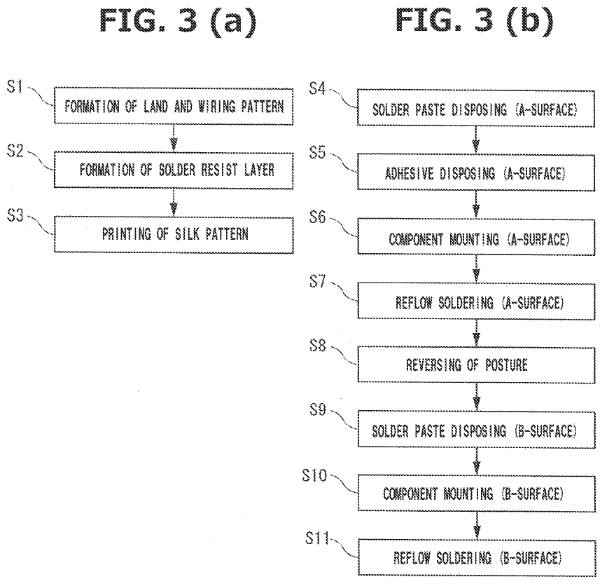

FIG. 3 is a flowchart showing one example of a producing process of the circuit board 3. FIG. 3(a) shows a process until the circuit board 3 before the components shown in FIG. 4 and FIG. 5 are mounted is obtained. In a process shown as a step 1, in each of the A-surface 3A and the B-surface 3B, the lands 22 and the wiring patters are formed by the etching of the metal foil layer of the base material surface. In addition, the plating processing of the through holes 28 is carried out, as needed.

Next, in a step 2, the formation of the solder resist layer is carried out to each of the A-surface 3A and the B-surface 3B. As mentioned above, the solder resist layer is formed by developing type solder resist formed in such a manner that ultraviolet rays are irradiated through a mask after resist ink is sprayed, and then carrying out developing processing so as to form a solder resist layer at a required position. Therefore, the forming process of the solder resist layer in the step 2 includes processes of the spraying of the resist ink, drying at approximately 80° C. (precure), exposure, developing, water washing, and curing at approximately 150° C. (post cure).

As a solder resist, for example, “PSR-4000 AM02SP/CA-40 AM02SP-K” that is a two-component developing type solder resist for electrostatic spray which can be obtained from TAIYO INK MFG. CO., LTD.

located in Saitama Prefecture in Japan can be used. It is desirable that the film thickness after the curing is 10 to 20 μm.

Next, in a step 3, the formation of the silk pattern 24 by printing is carried out to each of the A-surface 3A and the B-surface 3B. The silk pattern 24 is one formed by, after carrying out screen printing to a predetermined pattern including characters and numerals by using, for example, a thermosetting ink, being heated and dried so as to be cured. As a part of the silk pattern 24, the intermediate bonding film 24a for the adhesive 23 is formed. The silk pattern formation process in the step 3 includes processes of the pretreatment of the board, the application by the screen printing, and the curing by hot air at approximately 140° C. As an ink for the silk pattern 24, for example, “S-100Y N8-240Ps” that is a thermosetting ink which can be obtained from TAIYO INK MFG. CO., LTD. located in Saitama Prefecture in Japan can be used. It is desirable that the film thickness after the curing is 15 to 20 μm.

FIG. 3(b) shows a process for mounting electronic components to the circuit board 3 formed in the steps 1 to 3. In a step 4, solder material such as solder paste is disposed on each land 22 (22a, 22b) of the A-surface 3A. In addition, the process of each of the steps 4 to 7 is carried out in a posture in which the A-surface 3A of the circuit board 3 faces upward.

Next, in a step 5, adhesives 23 are disposed in a dot shape onto intermediate bonding films 24a of the A-surface 3A by a dispenser. Here, as an adhesive element, a thermosetting adhesive 23 is used. Then, in a step 6, before the curing of the adhesives 23, electronic components including aluminum electrolytic capacitors 21 are mounted (temporarily placed) at positions corresponding to each land 22 (22a, 22b) by using a mounter. At this time, the aluminum electrolytic capacitors 21 are placed on the adhesives 23, and are bonded to the surface of the circuit board 3, specifically, the surfaces of the intermediate bonding films 24a via the adhesives 23. Since a seat part 21 of each of the aluminum electrolytic capacitors 21 presses the dot-shaped adhesives 23, the adhesives 23 are expanded in a circular shape in the respective intermediate bonding films 24. In addition, the supplying of the adhesives 23 may be carried out before disposing the solder paste in the step 4.

Next, in a step 7, the circuit board 3 mounting the electronic components is heated by hot air in a reflow furnace so as to carry out reflow soldering by melting solder material. The reflow soldering in the step 7 includes processes of preheating at approximately 150° C., main heating at approximately 240° C., and cooling. The adhesives 23 bonded to the seat part 21b of each of the aluminum electrolytic capacitors 21 and the intermediate bonding films 24a therebetween are cured by being heated in a reflow furnace, thereby fixing the aluminum electrolytic capacitors 21 on the circuit board 3. Therefore, each of the aluminum electrolytic capacitors 21 is supported on the circuit board 3 at four points of a pair of electrode parts 21c soldered to lands 22 (22a) and a pair of adhesives 23.

As the adhesive 23, for example, “LOCTITE3621” that is a thermosetting epoxy adhesive which can be obtained from Henkel AG & Co. KGaA can be used. This material is cured at a temperature equal to or higher than 100° C., for example, approximately 150° C.

When the mounting of the electronic components to the A-surface 3A is finished, in a step 8, the posture of the circuit board 3 is reversed so as to be a posture in which the B-surface 3B faces upward. In a step 9, solder material such as solder paste is disposed to each land 22 (22b) of the B-surface 3B. Then, in a step 10, electronic components, such as a CPU 31, are mounted (temporarily placed) at positions corresponding to each of the lands 22 (22b) by using a mounter.

Next, in a step 11, similar to the step 7, the circuit board 3 mounting the electronic components on the B-surface 3B is heated by hot air in a reflow furnace so as to carry out reflow soldering by melting the solder material. The reflow soldering in the step 7 includes processes of preheating at approximately 150° C., main heating at approximately 240° C., and cooling.

In the process of the reflow soldering of the B-surface 3B in the step 11, there is a case where the soldered parts of the electronic components on the A-surface 3A in which the soldering has already been completed are also heated, and then the solder material is softened. In particular, there is possibility that since the A-surface 3A has a downward posture, when the solder material is softened, the electronic components fall off by their own weights. However, in the above embodiment, the aluminum electrolytic capacitors 21 that are large components are bonded to the circuit board 3 with the adhesives 23, and therefore the falling-off due to the softening of the solder material is suppressed.

On the other hand, the adhesive 23 effective for suppressing the falling-off of a large electronic component (for example, an aluminum electrolytic capacitor 21) is shrunken accompanying with the heat curing, and with respect to the surface on which the adhesive 23 is bonded, stress in the direction along this surface is applied. In a case where a wiring pattern formed by a metal foil layer exists under the adhesive 23, there is possibility that due to the stress accompanying with the shrinking, break of the wiring pattern occurs. To solve such a problem, in the configuration of the above embodiment, the adhesive 23 is not directly bonded to a solder resist layer covering the wiring pattern, and an intermediate bonding film 24a formed by a silk pattern 24 is interposed between the solder resist layer and the adhesive 23. This intermediate bonding film 24a can be regarded as a kind of elastic coating films made of ink of the silk pattern 24, and thereby when the adhesive 23 is thermally shrunken, stress applied to the solder resist layer and the wiring pattern, as an external force, is relaxed by the interposing of the intermediate bonding film 24a. The intermediate bonding film 24a, in a cured state, is preferably made of a material lower in hardness than the solder resist layer after being cured.

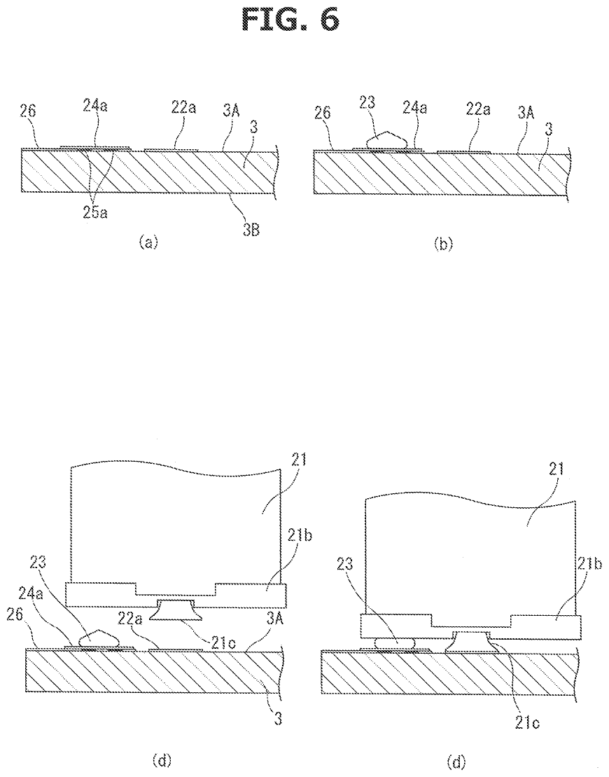

FIG. 6 is an explanatory view of a process showing a bonding process of an aluminum electrolytic capacitor 21 to which the above adhesive 23 is used. The drawing of a process (a) shows a main part of a circuit board 3 before a component are mounted, a pair of wiring patterns 25a and a land 22 (22a) each made of a metal foil layer (for example, copper foil) are formed thereon, and a solder resist layer 26 is provided so as to cover the wiring patterns 25a. Then, a circular intermediate bonding film 24a is provided on the solder resist layer 26 so as to correspond to a part to which the adhesive 23 is applied. With respect to such a circuit board 3, as shown in a process (b), the adhesive 23 is supplied in a dot shape to the middle of the circular intermediate bonding film 24a. Then, as shown in a process (c), the aluminum electrolytic capacitor 21 is mounted (temporarily placed). With this, as shown in a process (d), the aluminum electrolytic capacitor 21 is bonded.

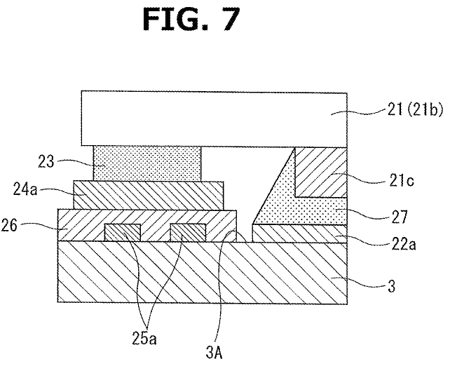

FIG. 7 is an explanatory view schematically showing cross-sectional structures of the soldering part and the adhesive part of the aluminum electrolytic capacitor 21 attached to the A-surface 3A of the circuit board 3 in the above way. As shown in the drawing, an electrode part 21c of the aluminum electrolytic capacitor 21 is soldered to a land 22a via a solder 27 by a reflow soldering method. The wiring patterns 25a made of the same metal fail layer as the land 22a are covered with the solder resist layer 26, and the intermediate bonding film 24a formed by a silk pattern 24 is laminated thereon. An electronic component, namely, the aluminum electrolytic capacitor 21 is bonded to the intermediate bonding film 24a via the thermosetting adhesive 23.

In this way, the intermediate bonding film 24a is interposed, and thereby stress due to the thermal shrinking of the adhesive 23 is relaxed. Consequently, even if the wiring patterns 25a exist under the adhesive 23, the possibility of the brake of the wiring patterns 26a is reduced.

In addition, even in a case where the stress is not absorbed sufficiently by the elasticity of the intermediate bonding film 24a, since the intermediate bonding film 24a is superposed so as to increase an interface, the peeling at the interface is expected. In particular, it is desirable that at least one of the bonding force in an interface 41 between the intermediate bonding film 24a and the adhesive 23 and the bonding force in an interface 42 between the intermediate bonding film 24a and the solder resist layer 26 is smaller than the bonding force in an interface 43 between the solder resist layer 26 and the base material surface of the circuit board 3. In a preferable example, the bonding force in the interface 41 between the intermediate bonding film 24a and the adhesive 23 is smaller than the bonding force in the interface 43 between the solder resist layer 26 and the base material surface of the circuit board 3, or the bonding force in the interface 42 between the intermediate bonding film 24a and the solder resist layer 26 is smaller than the bonding force in the interface 43 between the solder resist layer 26 and the base material surface of the circuit board 3. According to such a configuration, the peeling in the interface 41 or 42 occurs before the break of the wiring patterns 25a covered with the solder resist layer 26 occurs. In addition, since the aluminum electrolytic capacitor 21 is bonded to the circuit board 3 at two positions and the electrode part 21 of each of the two positions is soldered to the land 22a, even if a part of adhesives 23 is peeled at the interface, the falling-off of the aluminum electrolytic capacitor 21 does not always occur.

In this way, in the above embodiment, by interposing the intermediate film 24a between the adhesive 23 and the solder resist layer 26, the stress of the solder resist layer 26 is reduced, and the application of external force to the wiring patterns 25a covered with the solder resist layer 26 can be suppressed. Consequently, it becomes possible to provide the wiring patterns 25a so as to pass under the adhesive 23, a degree of freedom in designing increases, and the size of the circuit board 3 can be reduced.

In the above embodiment, the intermediate bonding film 24a is formed by printing as a part of the silk pattern 24. Therefore, actually there is no increase in the number of processes, and an actual change in the producing device of the circuit board 3 is not necessary. That is, it can be coped with only a change in the printing pattern of the silk pattern 24.

However, in the present invention, separately from the silk pattern 24, an intermediate bonding film made of a suitable material may be formed on the solder resist layer 26.

As the above, although one embodiment of the present invention has been explained in detail, the present invention is not limited to the above embodiment, and various modification can be carried out. For example, as an adhesive element, an adhesive other than thermosetting adhesives or a resin material having adhesiveness can be also used, and as an insulation film, one other than solder resist can be also used. In addition, the present invention can be applied for the mounting of an electronic component other than the aluminum electrolytic capacitor 21, as an electronic component.

As the above, an electronic circuit device of the present invention includes: a housing; and a circuit board accommodated in the housing and including an electronic component surface-mounted thereon, wherein a component mounting surface of the circuit board is provided with an insulation film for covering a wiring pattern and a land exposed from the insulation film, wherein the electronic component includes an electrode part connected to the land by soldering and a non-electrode part fixed to the insulation film via an adhesive element, and wherein, in the surface of the circuit board, an intermediate bonding film is provided at a part to which the adhesive element is disposed so as to be superposed on the insulation film, and the intermediate bonding film is interposed between the adhesive element and the insulation film.

In one preferable aspect, the intermediate bonding film is made from a coating film formed on the insulation film by printing.

More preferably, the coating film is formed by a part of a silk pattern including a character or a numeral displayed on the insulation film.

It is preferable that the intermediate bonding film is made of a material lower in hardness than the insulation film.

In addition, in another preferable aspect, at least one of a bonding force in an interface between the intermediate bonding film and the adhesive element and a bonding force in an interface between the intermediate bonding film and the insulation film is smaller than a bonding force in an interface between the insulation film and the circuit board.

For example, the bonding force in the interface between the intermediate bonding film and the adhesive element is smaller than the bonding force in the interface between the intermediate bonding film and the insulation film.

Alternatively, the bonding force in the interface between the intermediate bonding film and the insulation film is smaller than the bonding force in the interface between the intermediate bonding film and the adhesive element.

Preferably, the intermediate bonding film is provided in a range larger than a formation range of the adhesive element.

A method for producing a circuit board in the present invention includes; forming a wiring pattern and a land to each of a first surface and a second surface of the circuit board, and applying an insulation film so as to cover the wiring pattern; forming an intermediate bonding film to a part corresponding to a mounting position of a first electronic component in the first surface, so as to be superposed on the insulation film; soldering an electrode part of the first electronic component to the land by a reflow soldering method after the first electronic component is bonded and fixed on the intermediate bonding film via an adhesive element, in a posture in which the first surface faces upward; and soldering an electrode part of a second electronic component to the land in the second surface by a reflow soldering method, in a posture in which the second surface faces upward.

In a preferable aspect, the intermediate film is formed as a part of a silk pattern including a character or a numeral displayed on the insulation film by printing.

1. An electronic circuit device comprising:
a housing; and
a circuit board accommodated in the housing and including an electronic component surface-mounted thereon,
wherein a component mounting surface of the circuit board is provided with an insulation film for covering a wiring pattern and a land exposed from the insulation film,
wherein the electronic component includes an electrode part connected to the land by soldering and a non-electrode part fixed to the insulation film via an adhesive element, and
wherein, in the surface of the circuit board, an intermediate bonding film is provided at a part to which the adhesive element is disposed so as to be superposed on the insulation film, and the intermediate bonding film is interposed between the adhesive element and the insulation film.

2. The electronic circuit device according to claim 1, wherein the intermediate bonding film is made from a coating film formed on the insulation film by printing.

3. The electronic circuit device according to claim 2, wherein the coating film is formed by a part of a silk pattern including a character or a numeral displayed on the insulation film.

4. The electronic circuit device according to claim 1, wherein the intermediate bonding film is made of a material lower in hardness than the insulation film.

5. The electronic circuit device according to claim 1, wherein at least one of a bonding force in an interface between the intermediate bonding film and the adhesive element and a bonding force in an interface between the intermediate bonding film and the insulation film is smaller than a bonding force in an interface between the insulation film and the circuit board.

6. The electronic circuit device according to claim 5, wherein the bonding force in the interface between the intermediate bonding film and the adhesive element is smaller than the bonding force in the interface between the intermediate bonding film and the insulation film.

7. The electronic circuit device according to claim 5, wherein the bonding force in the interface between the intermediate bonding film and the insulation film is smaller than the bonding force in the interface between the intermediate bonding film and the adhesive element.

8. The electronic circuit device according to claim 1, wherein the intermediate bonding film is provided in a range larger than a formation range of the adhesive element.

9. A method for producing a circuit board, comprising:
forming a wiring pattern and a land to each of a first surface and a second surface of the circuit board, and applying an insulation film so as to cover the wiring pattern;
forming an intermediate bonding film to a part corresponding to a mounting position of a first electronic component in the first surface, so as to be superposed on the insulation film;
soldering an electrode part of the first electronic component to the land by a reflow soldering method after the first electronic component is bonded and fixed on the intermediate bonding film via an adhesive element, in a posture in which the first surface faces upward; and
soldering an electrode part of a second electronic component to the land in the second surface by a reflow soldering method, in a posture in which the second surface faces upward.

10. The method for producing the circuit board according to claim 9, wherein the intermediate film is formed as a part of a silk pattern including a character or a numeral displayed on the insulation film by printing.
